(19) United States
(12) Patent Application Publication
(10) Pub. No.: US 2016/0281236 A1
(43) Pub. Date: Sep. 29, 2016

(54) SUBSTRATE PROCESSING USING INTERLEAVED LOAD LOCK TRANSFERS

(71) Applicant: Alta Devices, Inc., Sunnyvale, CA (US)

(72) Inventors: Alexander Lerner, San Jose, CA (US); Brian Brown, Palo Alto, CA (US); Teresa Ann Trowbridge, Los Altos, CA (US); Joseph Foster, San Jose, CA (US)

(73) Assignee: Alta Devices, Inc., Sunnyvale, CA (US)

(21) Appl. No.: 14/669,250

(22) Filed: Mar. 26, 2015

(51) Int. Cl. C23C 16/46; C23C 16/455

(52) U.S. Cl. CPC C23C 16/46; C23C 16/463; C23C 16/455

(57) ABSTRACT

A substrate processing system having a hot reactor with two load locks and two associated load/unload units, and a related method of operating the system, are disclosed. Substrates are concurrently moved from the reactor into one of two load locks and from the other of the two load locks into the reactor. A bidirectional transfer mechanism is used for the concurrent transfers, such that successive transfers in opposite directions are interleaved. Substrates are heated in the load locks prior to processing in the reactor. The reactor applies processing to substrates, to form processed substrates. Processed substrates are cooled in the load locks after processing in the reactor. Respective load and unload units load substrates into the load locks and unload processed substrates from the load locks. The interleaved concurrent transfers minimize or make zero the idle time of the reactor.

### TECHNICAL FIELD

The technical field of the present disclosure relates to substrate processing and load locks, more particularly to systems and methods that transfer substrates to and from a processing chamber or reactor and to and from a load lock.

### BACKGROUND ART

When processing one or more substrates in a reactor, such as a chemical vapor deposition reactor, a load lock is generally employed. A load lock functions similarly to an airlock, and serves to prevent cross-contamination between an ambient environment and the reactor environment. The load lock holds one or more substrates, which are transferred from the load lock into the reactor for processing. Some systems have two load locks, one on either side of the reactor, and the second load lock receives wafers or other substrates from the reactor after processing. Such systems have a unidirectional substrate flow, as the substrates are moved from one load lock into the reactor for processing, and then from the reactor to the other load lock after processing. Each load lock employs an isolation seal, such as a door or a gate or other isolation device such as a gas curtain, between the load lock and the reactor. The other side of the load lock also employs an isolation seal, separating the load lock from either the ambient environment or a load and unload unit. The isolation seals can support pressure and/or temperature differences from one chamber or unit to the next. Load and unload units can be robotic in nature and provide automated loading and unloading of load locks.

Types of substrates eligible for processing in a reactor include both glass, e.g. as used in flat-panel displays, and semiconductor wafer substrates, such as those used to make solar photovoltaic cells or integrated circuits. Substrates may be mounted in a substrate carrier or on a susceptor. The substrates can be processed individually or in groups, depending on substrate size, reactor chamber size, processing sequence and other factors. Substrates can be moved using a transport mechanism, which can include a conveyor belt, one or more shuttles operated individually or in a train, rollers, air or other gas levitation, or magnetic coupling.

A reactor can include one or more processing chambers, and may perform one or more types of semiconductor processing steps such as diffusion, etching, deposition, or cleaning. Often, the amount of time substrates spend in the reactor, being processed, is the major factor affecting processing throughput and operating efficiency of a system. Reactor idle time, during which the reactor is not applying processing, reduces throughput and operating efficiency. Reactor idle time may occur while the reactor is waiting for wafers to be preheated, waiting for wafers be cooled, waiting for wafers to be moved into or out of the reactor and at other waiting times. Improvements in processing throughput and operating efficiency of systems using reactors for substrate processing are sought.

### SUMMARY

A method for operating a hot reactor between two load locks, and a related system for substrate processing are disclosed herein. The method and system are suitable for processing various substrates singly or in groups. Concurrent transfers of substrates from the reactor to the first load lock and from the second load lock to the reactor are interleaved with concurrent transfers of substrates from the reactor to the second load lock and from the first load lock to the reactor.

In an embodiment of the method, a hot reactor has two load locks. Substrates are concurrently moved from the reactor to a second load lock and from a first load lock into the reactor, in transfers in a first direction. Further substrates are concurrently moved from the reactor to the first load lock and from the second load lock into the reactor, in transfers in a second direction. The transfers in the first direction are interleaved with the transfers in the second direction, during a continuous operation of the reactor and the first and second load locks. The interleaved transfers minimize or make zero the reactor idle time. The substrates and the further substrates are transferred and processed individually or in groups.

More specifically, a hot reactor is located between two load locks. A processed first substrate is moved from the reactor to the first load lock. Concurrently with this move, a heated second substrate is moved from the second load lock to the reactor. The first substrate is cooled in the first load lock. The cooled first substrate is unloaded from the first load lock. A third substrate is loaded into the first load lock. The third substrate is heated in the first load lock. Substrate processing is applied to the second substrate in the reactor. The substrate processing is applied while the first substrate is being cooled in and then unloaded from the first load lock and the third substrate is being loaded into the first load lock and heated therein. The processed second substrate is moved from the reactor to the second load lock. Concurrently with this move, the heated third substrate is moved from the first load lock to the reactor. The second substrate is cooled in the second load lock. The cooled second substrate is unloaded from the second load lock. A fourth substrate is loaded into the second load lock. The fourth substrate is heated in the second load lock. Further substrate processing is applied to the third substrate in the reactor. The substrate processing is applied while the second substrate is being cooled in and then unloaded from the second load lock and the fourth substrate is being loaded into the second load lock and heated therein. A processing duration as applied to substrates being processed in the reactor is greater than an unload duration as applied to unloading substrates from the load locks plus a load duration is applied to loading substrates into the load locks. A cycle time of processing multiple such substrates is reduced and a throughput is increased as compared to using only a single load lock with the reactor.

The system for substrate processing includes a reactor, first and second load locks, first and second load and unload units and a bidirectional transfer mechanism. The first and second load locks are both connected to the reactor, can heat substrates therein before the substrates are moved into the reactor, and can also cool substrates after they are moved from the reactor. The first and second load and unload units are connected to the respective first and second load locks so as to be able to load and unload substrates into and out of those load locks. The bidirectional transfer mechanism can, in a first transfer direction, concurrently transfer (1) heated substrates from the first load lock into the reactor and (2) processed substrates from the reactor into the second load lock. Likewise, the bidirectional transfer mechanism can, in a second transfer direction, concurrently transfer (1) heated substrates from the second load lock into the reactor and (2) processed substrates from the reactor into the first load lock.

In an alternate embodiment, there can be two parallel reactor systems, each with their own sets of load and unload units and load locks, but both sharing a common gas box and related plumbing to supply the process gas to the respective reactors. In such a case, it may be advantageous to stagger the load-process-unload cycles of the parallel reactor systems so that the reactors do not require simultaneous use of the shared gas box.

### BRIEF DESCRIPTION OF THE DRAWINGS

FIGS. 1-16 are schematic diagrams showing interleaved transfers of substrates in a reactor-based system for substrate processing, in accordance with the present invention. The system includes a central reactor, two load locks and two load and unload units.

FIG. 17 is a timing diagram showing in the upper half of the diagram the operation of the reactor-based system of FIG. 1.

FIG. 18 is a schematic diagram of a further embodiment of a reactor-based system, as in FIG. 1 but including two reactors, four load locks and four load and unload units. FIG. 17 further shows, in both upper and lower halves of the diagram, staggered operation of this embodiment.

### DETAILED DESCRIPTION

As shown in FIGS. 1-18, embodiments of a reactor-based system 100 for substrate processing and a related method of operation thereof achieve high efficiency and substrate processing throughput. Transfers of substrates are coordinated in an interleaved manner so that idle time for the reactor is minimized or made zero, thus improving efficiency and throughput. In particular, preheating and post-process cooling of substrates take place inside load locks at the same time that processing of another substrate is performed within the reactor. Transfers into and out of the reactor occur concurrently through separate load locks.

With reference to FIG. 1, the reactor-based system 100 for substrate processing includes a reactor 106. Examples of suitable reactors include chemical vapor deposition reactors, showerhead reactors and semiconductor processing reactors. A first load lock 104 and a second load lock 108 are connected to opposite sides of the reactor 106, although other arrangements may be used. A first load and unload unit 102 is connected to the first load lock 104. A second load and unload unit 110 is connected to the second load lock 108. Respective isolation seals 112, 114, 116, 118, 120, 122 can be individually opened or closed to allow passage of substrates or isolate neighboring units in support of differing pressures and/or temperatures.

The embodiment of FIG. 1 has a linear arrangement of the first load and unload unit 102, the first load lock 104, the reactor 106, the second load lock 108 and the second load and unload unit 110, although other arrangements can be used in further embodiments. A first (optional) isolation seal 112 isolates one end of the first load and unload unit 102 from the ambient environment or further equipment, or selectively opens thereto: A second isolation seal 114 opens to connect or seals to isolate the first load and unload unit 102 and the first load lock 104. A third isolation seal 116 opens to connect or seals to isolate the first load lock 104 and the reactor 106. A fourth isolation seal 118 opens to connect or seals to isolate the reactor 106 and the second load lock 108. A fifth isolation seal 120 opens to connect or seals to isolate the second load lock 108 and the second load and unload unit 110. A sixth (optional) isolation seal 122 seals one end of the second load and unload unit 110 from the ambient environment or further equipment, or selectively opens thereto.

In sequence, FIGS. 1-16 show substrates being moved in an interleaved manner in a cycle of transfers involving the reactor 106, the first and second load locks 104, 108 and the first and second load and unload units 102, 110. In an ongoing or continuous process flow, the cycle of FIGS. 1-16 is repeated continuously. Initial steps for bringing up the system from a cold, unloaded state are not shown, and are readily devised. Such initial steps include initial loading of either or both of the load and unload units 102, 110, initial transfer to one of the load locks 104, 108, and loading of a substrate or group of substrates into the reactor 106 for the initial processing.

FIG. 1 starts the cycle from a steady state of operation. A group of processed substrates 124 (shown with diagonal shading bars) is present in the reactor 106. A group of substrates (shown with dotted shading) 126 is present in the second load lock 108, awaiting their turn for processing in the reactor 106. The substrates 126 may be unprocessed or preprocessed substrates, i.e. the substrates 126 have not yet received the next processing in the reactor 106, but may have received previous processing. Isolation seals 114, 120 between the load locks 104, 108 and the load and unload units 102, 110 are closed, and isolation seals 116, 118 at opposed sides of the reactor 106, i.e. between the reactor 106 and the load locks 104, 108 are opened. The reactor 106 and the load locks 104, 108 are pressure equalized and heated to a uniform, elevated temperature (shown as square grid shading), for example 400° C. Heating may be accomplished by convection, conduction or radiation, by using an electric heating element, heating lamps or other heat source. In the example shown, the substrates are in a group of three subgroups of sixteen substrates each, with each subgroup of sixteen substrates as four groups of four substrates. In further examples, a single substrate could be in the reactor 106 and a further single substrate could be in the second load lock 108, or other groups of substrates could be used. Multiple substrates may be moved on a carrier. Multiple carriers may be moved together in a group and processed in a chamber.

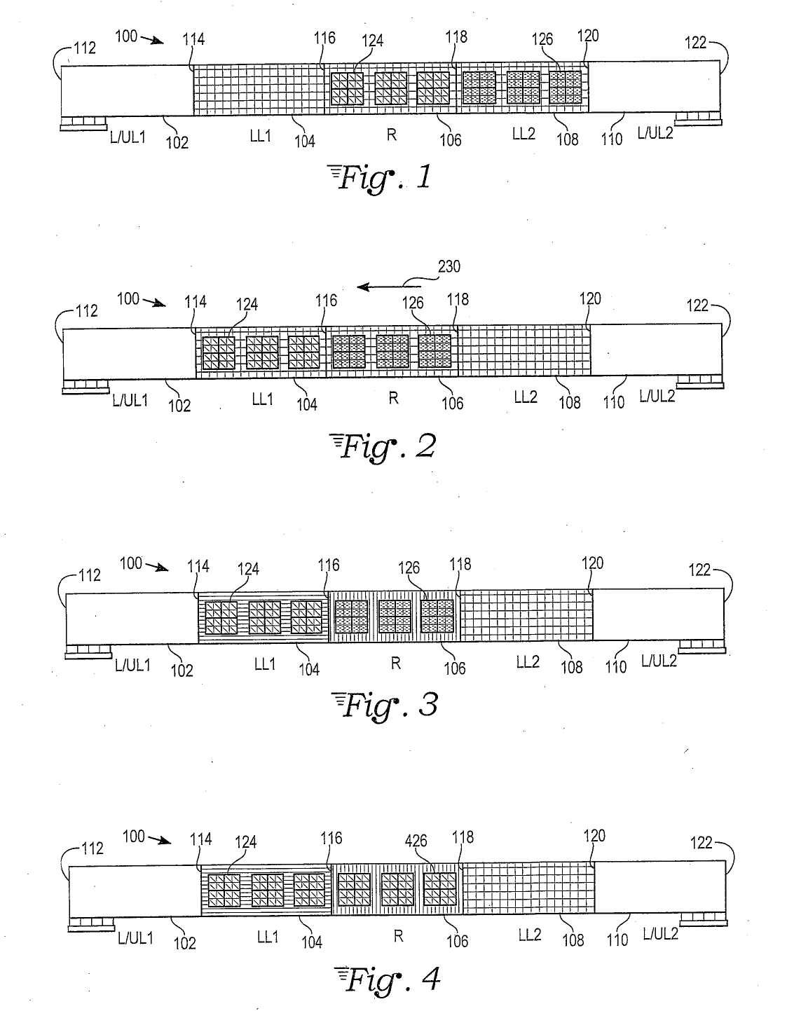

FIG. 2 follows FIG. 1 in the cycle. The processed substrates 124 and the substrates 126 that await processing are both moved concurrently in a two-one direction 230 (leftward in the drawing), for example by a transport mechanism that moves the substrates simultaneously. The processed substrates 124 are moved from the reactor 106 to the first load lock 104, and the substrates 126 are moved from the second load lock 108 to the reactor 106. In FIG. 2, the isolation seals 114, 116, 118, 120 and temperature equalizing remain as in FIG. 1. The concurrent moving of substrates out of and into the reactor 106 minimizes the reactor idle time. By comparison, sequentially moving the processed substrates 124 from the reactor to the first load lock 104, followed by moving the substrates 126 awaiting processing from the second load lock 108 to the reactor 106 would add to the reactor idle time because of the delay between the two sequential moves.

In FIG. 3, the isolation seals 116, 118 between the reactor 106 and the load locks 104, 108 are closed, which support differing pressures and/or temperatures. Isolation seals 114, 120 between the load locks 104, 108 and the respective load and unload units 102, 110 remained closed. The processed substrates 124 are being cooled in the first load lock 104 (shown as horizontal shading bars). Cooling may be accomplished by air cooling, gas cooling or liquid cooling, for example by circulating a cooling liquid through passages in a plate. The load lock 104 is being filled with gas, for example nitrogen, to raise the pressure to match that of the load and unload unit 102. Alternatively, load lock 104 can be cycle purged to reduce residual process gas species from reactor 106 prior to raising the pressure to match that of the load and unload unit 102. The substrates 126 in the reactor are being heated to a further elevated temperature (shown as vertical shading bars), for example 800° C.

FIG. 4 shows the substrates 126 receiving processing and becoming processed substrates 426 in the reactor 106, under the same temperature conditions as shown in FIG. 3.

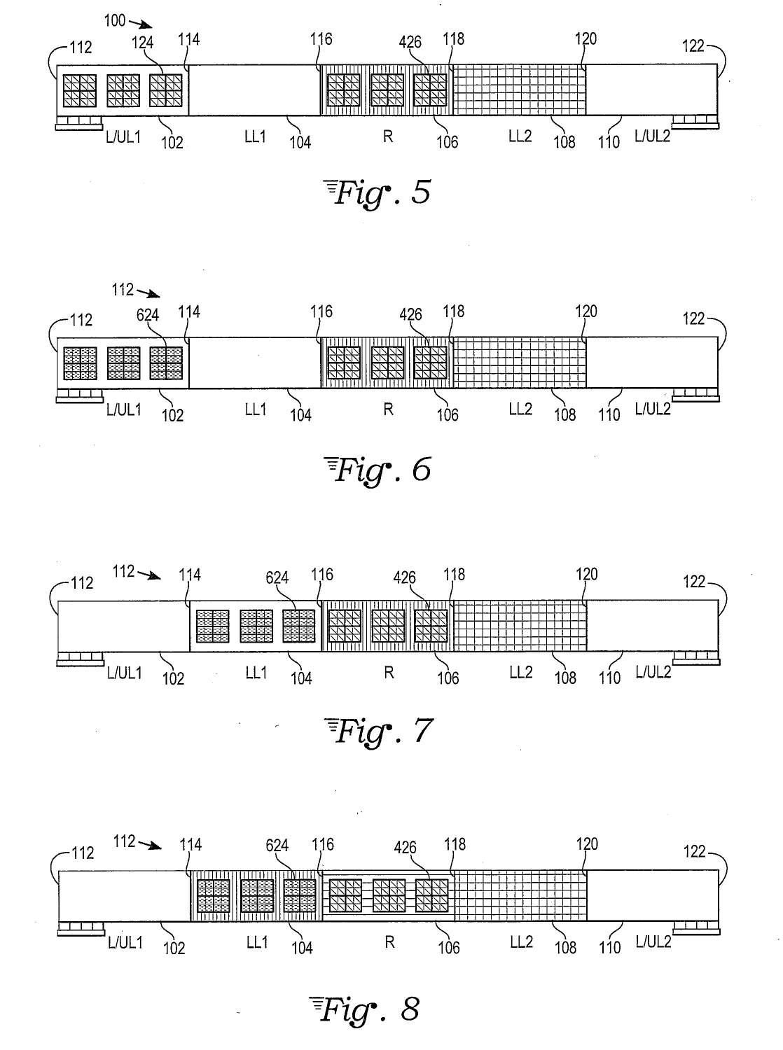

In FIG. 5, the processed substrates 124 that were moved out of the reactor 106 in FIG. 2 and cooled in the first load lock 104 are now moved from the first load lock 104 to the first load and unload unit 102. The isolation seal 114 between the first load and unload unit 102 and the first load lock 104 is open to permit passage of the processed substrates 124, and the first load and unload unit 102 and the first load lock 104 are at equal pressure, for example, atmospheric pressure (shown without shading). The substrates becoming processed substrates 426 continue to receive processing in the reactor 106, which remains at the further elevated temperature. The second load lock 108 remains at the elevated temperature. The isolation seals 116, 118 between the reactor 106 and the load locks 104, 108 remain closed, supporting the pressure and/or temperature difference.

In FIG. 6, the processed substrates 124 in the first load and unload unit 102 are exchanged for substrates 624, which may be unprocessed or preprocessed substrates. This is accomplished using a substrate handler, a robotic handler, or other automated or manual unloading of the processed substrates 124 and loading of the substrates 624. The substrates becoming processed substrates 426 continue to receive processing in the reactor 106, which remains at the further elevated temperature. The second load lock 108 remains at the elevated temperature. The isolation seals 116, 118 between the reactor 106 and the load locks 104, 108 remain closed, supporting the pressure and/or temperature difference.

In FIG. 7, the substrates 624 are moved from the first load and unload unit 102 into the first load lock 104. The isolation seal 114 between the first load and unload unit 102 and the first load lock 104 is open to permit passage of the substrates 624, and the first load and unload unit 102 and the first load lock 104 are at equal pressure (shown without shading). The substrates becoming processed substrates 426 continue to receive processing in the reactor 106, which remains at the further elevated temperature. The second load lock 108 remains at the elevated temperature. The isolation seals, 116, 118 between the reactor 106 and the load locks 104, 108 remain closed, supporting the pressure and/or temperature difference.

In FIG. 8, the isolation seals 116, 118 between the reactor 106 and the load locks 104, 108 are closed, which support differing pressures and/or temperatures. Isolation seals 114, 120 between the load locks 104, 108 and the respective load and unload units 102, 110 are closed. The processed substrates 426 are being cooled in the reactor 106 (shown as horizontal shading bars). Cooling may be accomplished by reducing the power input to the reactor heater. The substrates 624 in the first load lock 104 are being heated to an elevated temperature (shown as vertical shading bars), for example 400° C. The load lock 104 is being evacuated to lower the pressure to match that of the reactor 106. Alternatively, load lock 104 can be cycle purged to reduce residual contaminant gas species from the load and unload unit 102 prior to lowering the pressure to match that of reactor 106.

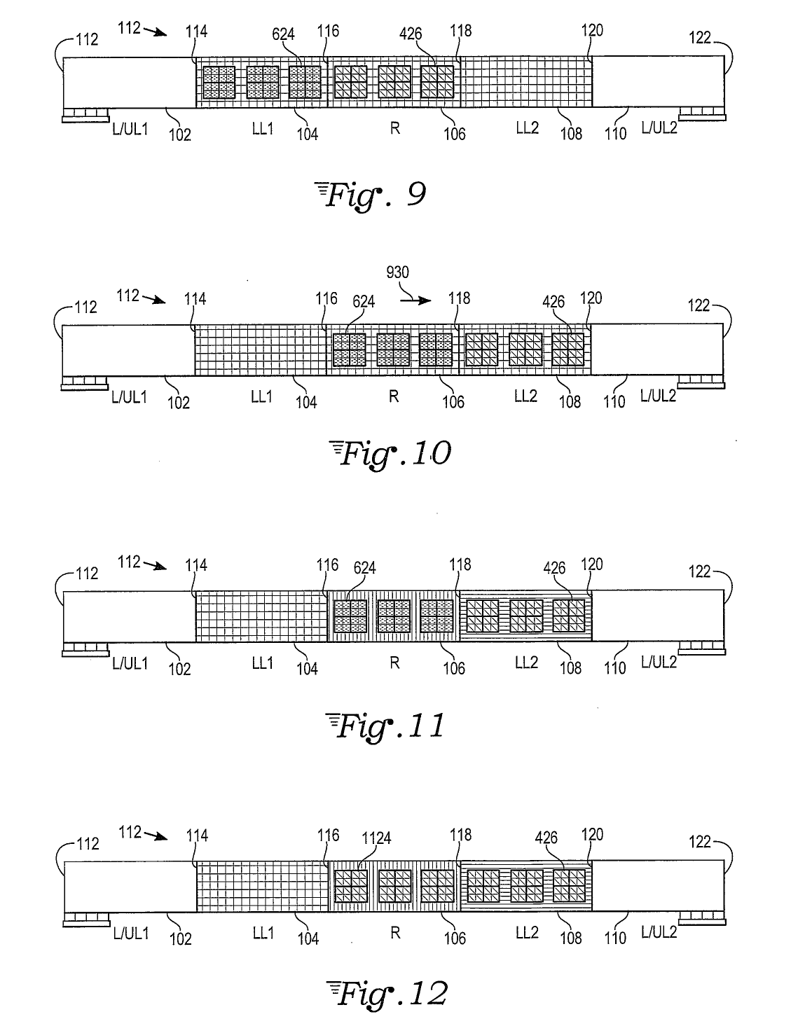

FIG. 9 shows the isolation seals 114, 120 between the load locks 104, 108 and the load and unload units 102, 110 are closed, and the isolation seals 116, 118 between the reactor 106 and the load locks 104, 108 are opened to support passage of substrates. The reactor 106 and the load locks 104, 108 are pressure equalized and at a uniform, elevated temperature (shown as square grid shading), for example 400° C. The processed substrates 426 are no longer receiving processing in the reactor 106.

In FIG. 10, the processed substrates 426 and the substrates 624 awaiting processing are both moved concurrently in a one-two direction 930 (rightward in the drawing), for example by a transport mechanism that moves the substrates simultaneously. The processed substrates 426 are moved from the reactor 106 to the second load lock 108, and the substrates 624 are moved from the first load lock 104 to the reactor 106. In FIG. 10, the isolation seals 114, 116, 118, 120 and temperature equalizing remain as in FIG. 9. The concurrent moving of substrates out of and into the reactor 106 minimizes the reactor idle time.

In FIG. 11, the isolation seals 116, 118 between the reactor 106 and the load locks 104, 108 are closed, which supports differing pressures and/or temperatures. Isolation seals 114, 120 between the load locks 104, 108 and the respective load and unload units 102, 110 remained closed. The processed substrates 426 are being cooled in the second load lock 108 (shown as horizontal shading bars). Cooling may be accomplished by air cooling, gas cooling or liquid cooling, for example by circulating a cooling liquid through passages in a plate. The load lock 108 is being filled with gas, for example nitrogen, to raise the pressure to match that of the load and unload unit 110. Alternatively, load lock 108 can be cycle purged to reduce residual process gas species from reactor 106 prior to raising the pressure to match that of the load and unload unit 110. The substrates 624 in the reactor are being heated to a further elevated temperature (shown as vertical shading bars), for example 800° C.

FIG. 12 shows the substrates 624 receiving processing and becoming processed substrates 1124 in the reactor 106, under the same temperature conditions as shown in FIG. 11.

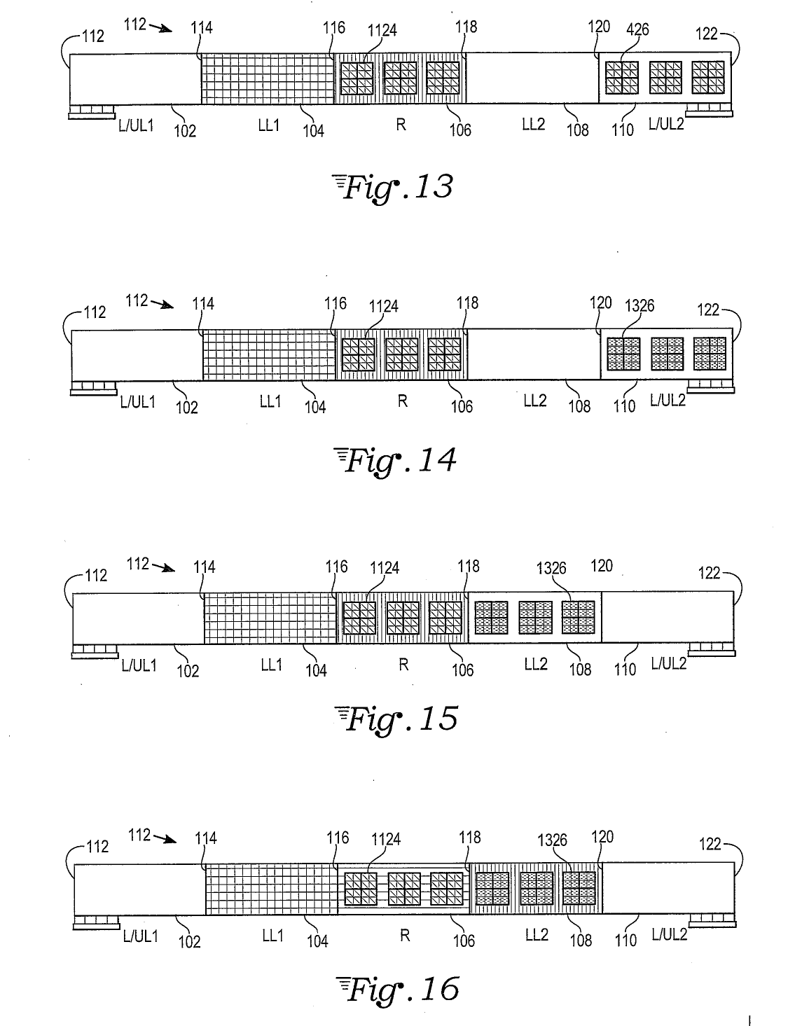

In FIG. 13, the processed substrates 426 that were moved out of the reactor 106 in FIG. 10 and cooled in the second load lock 108 are moved from the second load lock 108 to the second load and unload unit 110. The isolation seal 120 between the second load and unload unit 110 and the second load lock 108 is open to permit passage of the processed substrates 426, and the second load and unload unit 110 and the second load lock 108 are at equal pressure (shown without shading). The substrates becoming processed substrates 1124 continue to receive processing in the reactor 106, which remains at the further elevated temperature. The first load lock 104 remains at the elevated temperature. The isolation seals 116, 118 between the reactor 106 and the load locks 104, 108 remain closed, supporting the pressure and/or temperature difference.

In FIG. 14, the processed substrates 426 in the second load and unload unit 110 are exchanged for substrates 1326, which may be unprocessed or preprocessed substrates. This is accomplished using a substrate handler, a robotic handler, or other automated or manual unloading of the processed substrates 426 and loading of the substrates 1326. The substrates becoming processed substrates 1124 continue to receive processing in the reactor 106, which remains at the further elevated temperature. The first load lock 104 remains at the elevated temperature. The isolation seals 116, 118 between the reactor 106 and the load locks 104, 108 remain closed, supporting the pressure and/or temperature difference.

In FIG. 15, the substrates 1326 are moved from the second load and unload unit 110 into the second load lock 108. The isolation seal 120 between the second load and unload unit 110 and the second load lock 108 is open to permit passage of the substrates 1326, and the second load and unload unit 110 and the second load lock 108 are at equal pressure (shown without shading). The substrates becoming processed substrates 1124 continue to receive processing in the reactor 106, which remains at the further elevated temperature. The first load lock 104 remains at the elevated temperature. The isolation seals 116, 118 between the reactor 106 and the load locks 104, 108 remain closed, supporting the pressure and/or temperature difference.

In FIG. 16, the isolation seals 116, 118 between the reactor 106 and the load locks 104, 108 are closed, which support differing pressures and/or temperatures. Isolation seals 114, 120 between the load locks 104, 108 and the respective load and unload units 102, 110 are closed. The processed substrates 1124 are being cooled in the reactor 106 (shown as horizontal shading bars). Cooling may be accomplished by reducing the power input to the reactor heater. The substrates 1326 in the second load lock 108 are being heated to an elevated temperature (shown as vertical shading bars), for example 400° C. The load lock 108 is being evacuated to lower the pressure to match that of the reactor 106. Alternatively, load lock 108 can be cycle purged to reduce residual contaminant gas species from the load and unload unit 110 prior to lowering the pressure to match that of reactor 106. In an ongoing, continuous operation, FIG. 1 would follow FIG. 16, and the reactor would continue to receive substrates alternately from the first and second load locks, with interleaved concurrent transfers. The reactor would continue to move processed substrates alternately to the first and second load locks, with the interleaved concurrent transfers.

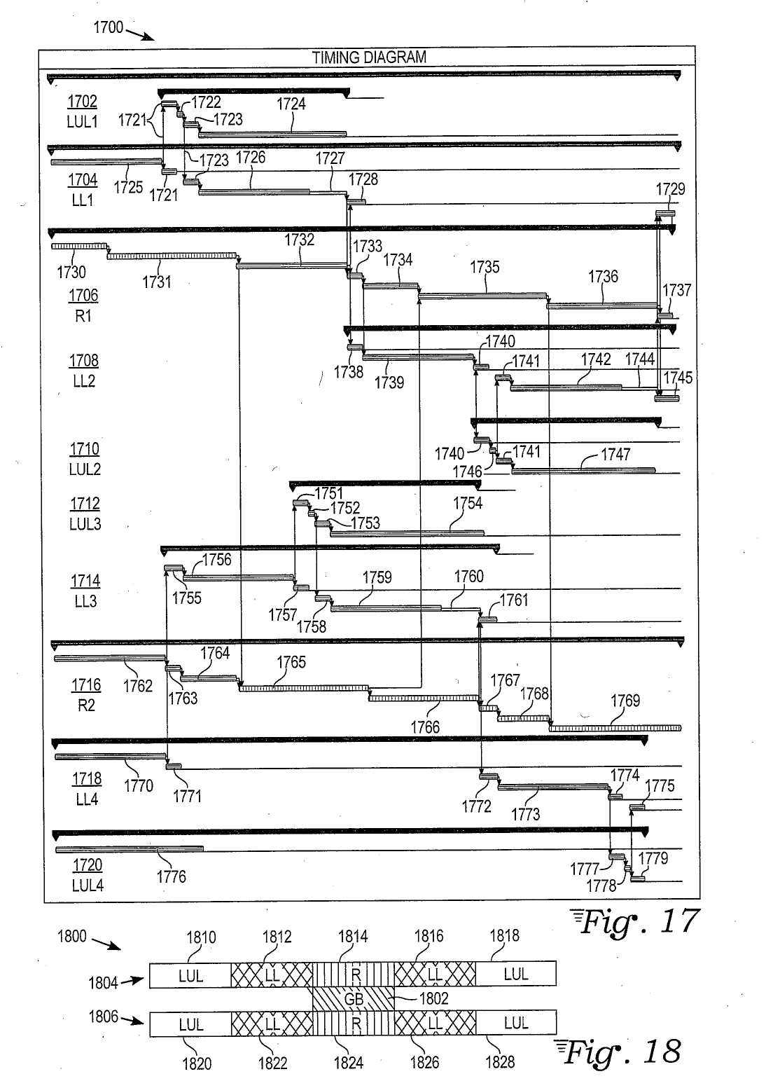

With reference to FIG. 17, a timing diagram 1700 is shown. The timing diagram 1700 shows an embodiment of an operation of the reactor-based system 100, as discussed below, and further shows an embodiment of an operation of the reactor-based system 1800 as will be discussed following presentation of FIG. 18.

From top to bottom, the timing diagram 1700 shows operation of components of the reactor-based system 100. A first region 1702 of the timing diagram 1700 shows operation of the first load and unload unit 102. A second region 1704 shows operation of the first load lock 104. A third region 1706 shows operation of the reactor 106, which may also be called the first reactor in a further embodiment. A fourth region 1708 shows operation of the second load lock 108. A fifth region 1710 shows operation of the second load and unload unit 110. The regions 1712-1720 show operations of a parallel system as considered below with reference to FIG. 18. Each of the regions 1702-1710 will now be described individually as they relate to the others, which complements the event-driven description of the reactor-based system 100 as described above with reference to FIGS. 1-16.

Starting with the first load and unload unit 102, from time zero on the timing diagram 1700, the unit 102 is initially idle or at least not involved in any transfers to or from the first load lock 104. Next, there is a transfer 1721 of processed substrates from the first load lock 104 to the first load and unload unit 102. Next, there is an index operation 1722. Next, there is a transfer 1723 of unprocessed or preprocessed substrates from the first load and unload unit 102 to the first load lock 104. Next there is a load and unload operation 1724 in the first load and unload unit 102, in which the processed substrates are unloaded and unprocessed or preprocessed substrates are loaded in preparation for the next transfer towards the reactor 106, i.e. a subsequent transfer from the first load and unload unit 102 to the first load lock 104. For the remainder of the time on the timing diagram 1700, the first load and unload unit 102 is idle or at least not involved in any transfers to or from the first load lock 104. The cycle then repeats (not shown).

Turning to the first load lock 104, from time zero on the timing diagram 1700, the first load lock 104 is performing a vent and/or cooling operation 1725 on processed substrates recently received from the reactor 106. Next, there is the transfer 1721 of the now cooled processed substrates from the first load lock 104 to the first load and unload unit 102. Next, there is the transfer 1723 of unprocessed or preprocessed substrates from the first load and unload unit 102 to the first load lock 104. Next, the substrates in the first load lock 104 awaiting processing are heated 1726, e.g. to 400° C. This may be performed by using a heating device or a heat pump. Next, after a brief idle time 1727 following the heating, there is a transfer 1728 of the now heated substrates from the first load lock 104 to the reactor 106. This transfer 1728 is included in a concurrent transfer 1733, discussed below. After these substrates are processed in the reactor 106, during which time the first load lock 104 is idle or at least not involved in any transfers, there is a transfer 1729 of the substrates from the reactor 106 to the first load lock 104. This transfer 1729 is included in a concurrent transfer 1737, discussed below. The cycle then repeats (not shown).

Considering now the reactor 106, from time zero on the timing diagram 1700, the reactor 106 is heating 1730, e.g. from 400° C. to 800° C., with substrates therein. These substrates were previously preheated, e.g. to 400° C., inside the second load lock 108 prior to being transferred into the reactor 106. Next, the reactor performs a processing operation 1731 on, for or with the substrates, such as a chemical vapor deposition. Next, the reactor is cooled 1732, e.g. from 800° C. to 400° C., with the processed substrates therein. Next, there is a concurrent transfer 1733 of the now processed substrates from the reactor 106 to the second load lock 108 and of the heated substrates from the first load lock 104 to the reactor 106. Next, the heated substrates recently transferred from the first load lock 104 are further heated 1734 in the reactor 106, e.g. from 400° C. to 800° C. Next, the reactor 106 performs a processing operation 1735 on, for or with the substrates, such as a chemical vapor deposition. Next, the reactor 106 is cooled 1736, e.g. from 800° C. to 400° C., with the processed substrates therein. Next, there is a concurrent transfer 1737 of the now processed substrates from the reactor 106 to the first load lock 104 and of the heated substrates from the second load lock 108 to the reactor 106. The cycle then repeats (not shown). As a result of the concurrent transfers 1733, 1737, the reactor experiences minimal or zero idle time.

Turning to the second load lock 108, from time zero on the timing diagram 1700, the second load lock 108 is idle or at least not involved in any transfers. After the substrates previously transferred from the second load lock 108 have finished being processed in the reactor 106, there is a transfer 1738 of processed substrates from the reactor 106 to the second load lock 108. This transfer 1738 is included in the concurrent transfer 1733. Next, the second load lock 108 performs a vent and/or cooling operation 1739 on the processed substrates recently received from the reactor 106. Next, there is a transfer 1740 of the now cooled processed substrates from the second load lock 108 to the second load and unload unit 110. Next, there is a transfer 1741 of unprocessed or preprocessed substrates from the second load and unload unit 110 to the second load lock 108. Next, the substrates in the second load lock 108 awaiting processing are heated 1742, e.g. to 400° C. This may be performed by using a heating device or a heat pump. Next, after a brief idle time 1744 following the heating, there is a transfer 1745 of the now heated substrates from the second load lock 108 to the reactor 106. This transfer 1745 is included in the concurrent transfer 1737, discussed above. The cycle then repeats (not shown).

And finally, considering the second load and unload unit, from time zero on the timing diagram 1700, the unit 110 is initially idle or at least not involved in any transfers to or from the second load lock 108. Next, there is the transfer 1740 of processed substrates from the second load lock 108 to the second load and unload unit 110. Next, there is an index operation 1746. Next, there is the transfer 1741 of unprocessed or preprocessed substrates from the second load and unload unit 110 to the second load lock 108. Next, there is a load and unload operation 1747 in the second load and unload unit 110, in which the processed substrates are unloaded and unprocessed or preprocessed substrates are loaded in preparation for the next transfer towards the reactor 106, i.e. a subsequent transfer from the second load and unload unit 110 to the second load lock 108. The cycle then repeats (not shown).

Operation of the second load lock 108 and second load and unload unit 110 with respect to the reactor 106 resembles a mirror image of the operation of the first load and unload unit 102 and the first load lock 104, except that the two sections of the reactor-based system 100 are 180 degrees or 50% out of phase with each other. The concurrent transfers 1733, 1737 are interleaved so that the reactor 106 is receiving substrates alternately from the first load lock 104 and the second load lock 108, and is sending processed substrates alternately to the first load lock 104 and the second load lock 108.

With reference to FIG. 18, a further embodiment of the reactor-based system 100 for substrate processing is shown. The reactor-based system 1800 includes two parallel reactor-based subsystems 1804, 1806 sharing a common gas box 1802, with manifolds connected thereto. Each of the subsystems 1804, 1806 resembles the reactor-based system 100 albeit with shared plumbing for the shared gas box 1802. Subsystem 1804 includes a first load and unload unit 1810 connected to a first load lock 1812 and a second load and unload unit 1818 connected to a second load lock 1816. The first and second load locks 1812, 1816 are connected to a first reactor 1814. Subsystem 1806 includes a third load and unload unit 1820 connected to a third load lock 1822, and a fourth load and unload unit 1828 connected to a fourth load lock 1826. The third and fourth load locks 1822, 1826 are connected to a second reactor 1824. The first and second reactors 1814, 1824 are connected to the shared gas box 1802.

When multiple reactors 1814, 1824 share a common gas box 1802 and associated plumbing, it may preferable that depositions or other processing operations applied by the reactors 1814, 1824 be staggered wherever gas flows may be insufficient for simultaneous deposition. However, if the common gas box 1802 has the capacity to handle simultaneous deposition in both reactors 1814, 1824, then staggered flows are not needed and the depositions might even be synchronized. FIG. 17, including now the bottom half of the figure, shows operation of the parallel dual-reactor-based system 1800 employing staggered processing operations. Moving of substrates into and out of the first and second reactors 1814, 1824 is coordinated with staggered phasing so that the substrate processing is applied in each of the first and second reactors 1814, 1824 in an alternating manner.

Referring back to FIG. 17, the timing diagram 1700 shows operation of the reactor-based system 1800. The first reactor-based subsystem 1804 includes the first load and unload unit 1810, the first load lock 1812, the first reactor 1814, the second load lock 1816 and the second load and unload unit 1818. The first reactor-based subsystem 1804 operates in accordance with the upper half of the timing diagram 1700, as previously described regarding the single-reactor-based system 100.

The second reactor-based subsystem 1806 operates in accordance with the lower half of the timing diagram 1700 in one embodiment, as now described. From time zero on the timing diagram 1700, the third load and unload unit 1820 is initially idle or at least not involved in any transfers to or from the third load lock 1822. Next, there is a transfer 1751 of processed substrates from the third load lock 1822 to the third load and unload unit 1820. Next, there is an index operation 1752. Next, there is a transfer 1753 of unprocessed or preprocessed substrates from the third load and unload unit 1820 to the third load lock 1822. Next there is a load and unload operation 1754 in the third load and unload unit 1820, in which the processed substrates are unloaded and unprocessed or preprocessed substrates are loaded in preparation for the next transfer towards the second reactor 1824, i.e. a subsequent transfer from the third load and unload unit 1820 to the third load lock 1822. For the remainder of the time on the timing diagram 1700, the third load and unload unit 1820 is idle or at least not involved in any transfers to or from the third load lock 1822. The cycle then repeats (not shown).

After substrates are processed in the second reactor 1824, during which time the third load lock 1822 is idle or at least not involved in any transfers, there is a transfer 1755 of the substrates from the second reactor 1824 to the third load lock 1822. This transfer 1755 is included in a concurrently transfer 1763, discussed below. Next, the third load lock 1822 is performing a vent and/or cooling operation 1756 on the processed substrates recently received from the second reactor 1824. Next, there is the transfer 1757 of the now cooled processed substrates from the third load lock 1822 to the third load and unload unit 1820. Next, there is the transfer 1758 of unprocessed or preprocessed substrates from the third load and unload unit 1820 to the third load lock 1822. Next, the substrates in the third load lock 1822 awaiting processing are heated 1759, e.g. to 400° C. This may be performed by using a heating device or a heat pump. Next, after a brief idle time 1760 following the heating, there is a transfer 1761 of the now heated substrates from the third load lock 1822 to the second reactor 1824. This transfer 1761 is included in a concurrent transfer 1767, discussed below. The cycle then repeats (not shown).

From time zero on the timing diagram 1700, the second reactor 1824 is cooled 1762, e.g. from 800° C. to 400° C., with the processed substrates therein. Next, there is a concurrent transfer 1763 of the now processed substrates from the second reactor 1824 to the third load lock 1822 and of the heated substrates from the fourth load lock 1826 to the second reactor 1824. Next, the second reactor 1824 is heating 1764, e.g. from 400° C. to 800° C., with the recently transferred heated substrates therein. These substrates were previously heated, e.g. to 400° C., in the fourth load lock 1826 prior to being transferred to the second reactor 1824. Next, the reactor performs a processing operation 1765 on, for or with the substrates, such as a chemical vapor deposition. Note in particular that in this staggered embodiment, the processing operation 1765 in the second reactor 1824 occurs at a different time from the corresponding processing operation 1735 in the first reactor 1814, so that the two operations do not coincide, so that the common gas box 1802 need not have to supply process gas to both reactors at once. Next, the reactor is cooled 1766, e.g. from 800° C. to 400° C., with the processed substrates therein. Next, there is a concurrent transfer 1767 of the now processed substrates from the second reactor 1824 to the fourth load lock 1826 and of the heated substrates from the third load lock 1822 to the second reactor 1824. Next, the heated substrates recently transferred from the third load lock 1822 are further heated 1768 in the second reactor 1824, e.g. from 400° C. to 800° C. Next, the second reactor 1824 performs a processing operation 1769 on, for or with the substrates, such as a chemical vapor deposition. The cycle then repeats (not shown). As a result of the concurrent transfers 1763, 1767, the reactor experiences minimal or zero idle time.

From time zero on the timing diagram 1700, the substrates in the fourth load lock 1826 awaiting processing are heated 1770, e.g. to 400° C. This may be performed by using a heating device or a heat pump. Next, there is a transfer 1771 of the now heated substrates from the fourth load lock 1826 to the second reactor 1824. This transfer 1771 is included in the concurrent transfer 1763, discussed above. While the substrates transferred from the fourth load lock 1826 to the second reactor 1824 are being processed in the second reactor 1824, the fourth load lock 1826 is idle or at least not involved in any transfers. After the substrates previously transferred from the fourth load lock 1826 have finished being processed in the second reactor 1824, there is a transfer 1772 of processed substrates from the second reactor 1824 to the fourth load lock 1826. This transfer 1772 is included in the concurrent transfer 1767 discussed above. Next, the fourth load lock 1826 performs a vent and/or cooling operation 1773 on the processed substrates recently received from the second reactor 1824. Next, there is a transfer 1774 of the now cooled processed substrates from the fourth load lock 1826 to the fourth load and unload unit 1828. Next, there is a transfer 1775 of unprocessed or preprocessed substrates from the fourth load and unload unit 1828 to the fourth load lock 1826. The cycle then repeats (not shown).

From time zero on the timing diagram 1700, there is a load and unload operation 1776 in the fourth load and unload unit 1828, in which processed substrates are unloaded and unprocessed or preprocessed substrates are loaded in preparation for the next transfer towards the second reactor 1824, i.e. a subsequent transfer from the fourth load and unload unit 1828 to the fourth load lock 1826. The fourth load and unload unit 1828 is then idle or at least not involved in any transfers to or from the fourth load lock 1826. Next, there is a transfer 1777 of processed substrates from the fourth load lock 1826 to the fourth load and unload unit 1828. Next, there is an index operation 1778. Next, there is a transfer 1779 of unprocessed or preprocessed substrates from the fourth load and unload unit 1828 to the fourth load lock 1826. The cycle then repeats (not shown).

Operating efficiency and substrate processing throughput of the reactor-based system 100 and the reactor-based system 1800 can be compared with another reactor-based system (not shown) that includes a single reactor, only a single load lock and only a single load and unload unit. Such a single reactor, single load lock system would have the reactor idle while substrates are exchanged out of the single load lock. The reactor would further be idle as a result of the separate unloading of processed substrates from the reactor and loading of unprocessed or preprocessed substrates into the reactor. Comparison shows that embodiments of the reactor-based system 100 have a reduced cycle time of processing substrates and an increased throughput as compared to using only a single load lock with a reactor.

In the case where a processing duration as applied to substrates being processed in the reactor is greater than unload duration as applied to unloading substrates from load locks plus a load duration as applied to loading substrates into the load locks, each of the load locks has an idle time. Meanwhile, the idle time of the reactor is minimized or made zero. A capital expenditure of purchasing two load locks is thus offset by improved productivity as measured by substrate processing throughput, in that maximal use is made of reactor time.

What is claimed is:

1. A method for operating a hot reactor between two load locks, comprising:
moving a processed first substrate from a reactor to a first load lock and concurrently moving a heated second substrate from a second load lock to the reactor;
cooling the first substrate in the first load lock;
unloading the cooled first substrate from the first load lock;
loading a third substrate into the first load lock;
heating the third substrate in the first load lock;
applying substrate processing to the second substrate in the reactor while the first substrate is being cooled in and then unloaded from the first load lock and the third substrate is being loaded into the first load lock and heated therein;
moving the processed second substrate from the reactor to the second load lock and concurrently moving the heated third substrate from the first load lock to the reactor;
cooling the second substrate in the second load lock;
unloading the cooled second substrate from the second load lock;
loading a fourth substrate into the second load lock;
heating the fourth substrate in the second load lock; and
applying a further substrate processing to the third substrate in the reactor while the second substrate is being cooled in and then unloaded from the second load lock and the fourth substrate is being loaded into the second load lock and heated therein; wherein:
a processing duration as applied to substrates being processed in the reactor is greater than an unload duration as applied to unloading substrates from the load locks plus a load duration as applied to loading substrates into the load locks; and
a cycle time of processing multiple such substrates is reduced and a throughput is increased as compared to using only a single load lock with the reactor.

2. The method of claim 1 further comprising repeating all of the steps of claim 1 with subsequent substrates in an ongoing cycling manner, interleaving transfers involving the first load lock with transfers involving the second load lock.

3. The method of claim 1 wherein the further substrate processing applied to the third substrate is of a same duration and a same type as the substrate processing applied to the first substrate.

4. The method of claim 1 wherein the further substrate processing applied to the third substrate is of a differing duration or a differing type from the substrate processing applied to the first substrate.

5. The method of claim 1 wherein the processing duration as applied to the second or third substrate in the reactor is greater than or equal to a further combined total duration of a cooling duration as applied to cooling the first or second substrate in the first or second load lock respectively, the unload duration as applied to unloading the first or second substrate from the first or second load lock respectively, the load duration as applied to loading the third or fourth substrate into the first or second load lock respectively plus a heating duration as applied to heating the third or fourth substrate in the first or second load lock respectively.

6. The method of claim 1 further comprising opening isolation seals between the first load lock and the reactor and between the reactor and the second load lock, prior to moving the processed first substrate from the reactor to the first load lock and concurrently moving the heated second substrate from the second load lock to the reactor or moving the processed second substrate from the reactor to the second load lock and concurrently moving the heated third substrate from the first load lock to the reactor.

7. The method of claim 6 further comprising keeping closed the isolation seals between the first load lock and the reactor and between the reactor and the second load lock throughout the applying the substrate processing to the second or third substrate in the reactor.

8. The method of claim 1 further comprising:
supplying the reactor with at least one gas from a shared gas box; and
supplying a further reactor from the shared gas box, the further reactor having a third load lock and a fourth load lock.

9. The method of claim 8 wherein moving substrates into and from the reactor and the further reactor is coordinated with staggered phasing so that the substrate processing is applied in the reactor and further substrate processing is applied in the further reactor in an alternating manner.

10. A method for operating a hot reactor with two load locks, comprising:
concurrently moving substrates from a reactor to a second load lock and from a first load lock into the reactor in transfers in a first direction;
concurrently moving further substrates from the reactor to the first load lock and from the second load lock into the reactor in transfers in a second direction; and
interleaving the transfers in the first direction with the transfers in the second direction during a continuous operation of the reactor and the first and second load locks; wherein:
the interleaved transfers minimize or make zero a reactor idle time; and
the substrates and the further substrates are transferred and processed individually or in groups.

11. The method of claim 10 wherein:
processed substrates are moved from the reactor into the second load lock concurrently with moving heated substrates from the first load lock into the reactor in the transfers in the first direction; and
processed further substrates are moved from the reactor into the first load lock concurrently with moving heated further substrates from the second load lock into the reactor in the transfers in the second direction.

12. The method of claim 10 further comprising:
loading the substrates from a first load and unload unit to the first load lock;
heating the substrates in the first load lock, prior to moving the substrates from the first load lock into the reactor;
cooling the substrates in the second load lock after processing the substrates in the reactor and moving the substrates to the second load lock;
unloading the cooled processed substrates from the second load lock to a second load and unload unit;
loading the further substrates from the second load and unload unit to the second load lock;
heating the further substrates in the second load lock, prior to moving the further substrates from the second load lock into the reactor;
cooling the further substrates in the first load lock after processing the further substrates in the reactor and moving the further substrates from the reactor to the first load lock; and
unloading the cooled processed further substrates from the first load lock to the first load and unload unit.

13. The method of claim 12 further comprising:
removing the cooled processed substrates and the cooled processed further substrates from the second load and unload unit and the first load and unload unit respectively; and
replenishing a supply of the substrates and the further substrates to the first load and unload unit and the second load and unload unit respectively.

14. The method of claim 12 further comprising:
closing isolation seals between the first load and unload unit and the first load lock and between the first load lock and the reactor prior to heating the substrates in the first load lock or cooling the processed further substrates in the first load lock; and
closing further isolation seals between the second load and unload unit and the second load lock in between the second load lock in the reactor prior to heating the further substrates in the second load lock or cooling the processed substrates in the second load lock.

15. The method of claim 12 further comprising keeping closed isolation seals between the first load and unload unit and the first load lock and between the second load lock and the second load and unlock unit, and keeping open isolation seals between the first load lock and the reactor and between the reactor and the second load lock during the transfers in the first direction and the transfers in the second direction.

16. A system for substrate processing, comprising:
a reactor that can apply semiconductor processing to substrates to form processed substrates;
a first load lock that is connected to the reactor and can heat the substrates before the substrates are moved to the reactor and cool the substrates after the substrates are moved from the reactor;
a first load and unload unit that is connected to the first load lock and can load and unload the substrates into and from the first load lock;
a second load lock that is connected to the reactor and can heat the substrates before the substrates are moved to the reactor and cool the substrates after the substrates are moved from the reactor;
a second load and unload unit that is connected to the second load lock and can load and unload the substrates into and from the second load lock; and
a bidirectional transfer mechanism that can concurrently transfer heated substrates from the first load lock into the reactor and processed substrates from the reactor into the second load lock in a first transfer and can concurrently transfer heated substrates from the second load lock into the reactor and processed substrates from the reactor into the first load lock in a second transfer.

17. The system of claim 16 wherein:
the first load lock is connected to a first side of the reactor; and
the second load lock is connected to a second side of the reactor.

18. The system of claim 16 further comprising respective isolation seals between the first load and unload unit and the first load lock, between the first load lock and the reactor, between the reactor and the second load lock, and between the second load lock and the second load and unload unit, that can individually open to allow passage of the substrates and close to isolate pressure and/or temperature.

19. The system of claim 16 further comprising:
a second reactor, wherein the reactor having the first load lock, the first load and unload unit, the second load lock and the second load and unload unit is a first reactor;
a third load lock that is connected to the second reactor;
a third load and unload unit that is connected to the third load lock;
a fourth load lock that is connected to the second reactor;
a fourth load and unload unit that is connected to the fourth load lock; and
a shared gas box connected to the first reactor and the second reactor.

20. The system of claim 16 further comprising the system being configured to interleave the first and second transfers in a continuous operation.
